(19) United States
(12) Patent Application Publication
(10) Pub. No.: US 2005/0009228 A1
(43) Pub. Date: Jan. 13, 2005

(54) Semiconductor device with higher oxygen (02) concentration within window layers and method for making

(76) Inventors: Xuanzhi Wu, Golden, CO (US); Ramesh Dhere, Lakewood, CO (US)

Correspondence Address: Paul J White;National Renewable Energy Laboratory, 1617 Cole Blvd, Golden, CO, 80401, US

(21) Appl. No.: 10/499,212

(22) PCT Filed: Dec. 13, 2001
(86) PCT No.: PCT/US01/48838

(51) Int. Cl. H01L 21/00

(52) U.S. Cl. 438/95

(57) ABSTRACT

A method for making a heterojunction photovoltaic device (200) is provided for converting solar radiation to photocurrent and photovoltage with improved efficiency. The method and apparatus include an improved window layer (230) having an increased oxygen (140) concentration with higher optical bandgap and photo to dark conductivity ratio. The improved photovoltaic device (200) is made using a deposition method which incorporates the use of a gas mixture of an inert gas (115) and a predetermined amount of oxygen (140), deposited at or near room temperature. Window layers contemplated by the present invention include, but are not limited to, cadmium sulfide (CdS) and various alloys of zinc cadmium sulfide (ZnₓCd₁₋ₓS). To further increase the efficiency of the resultant photovoltaic device (200), deposition parameters are controlled and monitored to improve the deposited window layer (230).

### CONTRACTURAL ORIGIN OF THE INVENTION

The United States Government has rights in this invention under Contract No. DE-AC36-99G010337 between the United States Department of Energy and the National Renewable Energy Laboratory, operated for U.S. Department of Energy by the Midwest Research Institute.

### TECHNICAL FIELD

The present invention relates to a method of making high efficiency energy conversion devices. More particularly, the present invention is directed to solar photovoltaic energy conversion devices that are produced using deposition methods having an oxygen-inert gas mixture to produce semiconductor layers with high oxygen content. Even more particularly, the present invention is directed to solar photovoltaic energy conversion devices with heterojunction structure that are produced using deposition methods having an oxygen-inert gas mixture to produce window layers with high oxygen content.

### BACKGROUND ART

1. Introduction to Photovoltaics

Photovoltaic (“PV”) cells convert light directly into electricity. PV cells are used in numerous applications, from small energy conversion devices for calculators and watches to large energy conversion devices for households, utilities, and satellites.

Typical commercial PV modules have an efficiency of 6-20%. Cell efficiency typically represents the efficiency of converting sunlight to electrical energy. However, solar cells having greater conversion efficiencies are still needed to bring the cost per watt of electricity produced into line with the cost of generating electricity with fossil fuels and nuclear energy.

PV cells are generally made of multiple layers of n-type and p-type semiconductor materials, which aid in the transfer of electrons. Layers of these materials are typically arranged in a manner to produce a circuit that produces a flow of electrons when photons are incident upon a cell. Cells normally include a top metallic grid and a back electrical contact to collect charge carriers from the semiconductor, and transfer the electrons to an external load. An anti-reflective coating is usually provided to reduce the reflection from the cell surface. Additionally, a protective transparent encapsulant layer is frequently placed over the cell to seal the cell and keep the harmful effects of weather out.

The basic physical process through which a PV cell converts sunlight into electricity is called the “photovoltaic effect.” Sunlight is composed of photons, or particles of solar energy. These photons contain various amounts of energy corresponding to the different wavelengths of the solar spectrum. When photons strike a PV cell, they may be reflected or absorbed, or they may pass right through the cell. Only absorbed photons generate electricity. Once a photon strikes the cell, the energy of the photon is transferred to an electron in an atom of the cell. With its new found energy, the electron is able to escape from its normal position associated with that atom to become part of the current in an electrical circuit. By leaving this position, the electron causes a “hole” to form. Special electrical properties of the PV cell, such as a built-in electric field, provide the voltage needed to drive the current through the cell to an external load.

When photons of sunlight strike a PV cell, only photons with a certain level of energy are able to free electrons from their atomic bonds to produce an electric current. This level of energy, known as the band-gap energy, is commonly defined as the amount of energy required to dislodge an electron from its covalent bond and allow it to become part of an electrical circuit. The energy that photons possess is called the “photon energy.” This energy must be at least as high as the band-gap energy for a photon to free an electron. However, when the photon energy is greater than the band-gap energy, the extra energy is released as heat when freeing the electrons. Ideally, one key to obtaining an efficient PV cell is to convert as much sunlight into electricity as possible.

Solar energy, essentially light, comprises electromagnetic radiation in a whole spectrum of wavelengths, i.e., discrete particles or photons at various energy levels, ranging from higher energy ultraviolet with wavelengths less than 390 nm to lower energy near-infrared with wavelengths as long as 3000 nm. Between these ultraviolet and infrared wavelengths or electromagnetic radiation energy levels are the visible light spectrum, comprising violet, blue, green, yellow, orange, and red wavelengths or energy bands.

Because a semiconductor layer of a solar cell absorbs photons with energy greater than the band gap of the semiconductor layer, a low band gap semiconductor layer absorbs most of the photons in the received solar energy. However, useful electrical power produced by the solar cell is the product of the voltage and the current produced by the solar cell during conversion of the solar energy to electrical energy. Although a solar cell made from a low band gap material may generate a relatively large current, the voltage is often undesirably low for many implementations of solar cells.

Effective PV semiconductors have band-gap energies ranging from 0.7 to 1.8 electron volts (eV). Semiconductor material is thus engineered to optimize a cell layer to levels of energy that are good for freeing electrons without causing extra heat. The photon energy of light, also measured in eV, varies according to the different wavelengths of light. For example, red light has an energy of about 1.7 eV, and blue light has an energy of about 2.7 eV. About 55% of the energy of sunlight cannot be used by most PV cells because this energy is either below the band gap (e.g., no electrons are freed) or carries excess energy (e.g., excess heat released).

Different PV materials have different characteristic energy band gaps. Photons with energy greater than the band gap may be absorbed to create charge carriers. Photons with energy less than the band gap pass through the material or create heat.

Therefore, the most important aspect of a solar cell is the semiconductor layers because this is where the electron current is created. There are a number of different materials suitable for making these semiconducting layers, each having its own benefits and drawbacks.

2. Description of the Related Art

A solar cell is essentially a semiconductor diode made of p and n type semiconductors. As such, solar cells can be divided into categories based on the characteristic of their diode structure. There are generally two categories, homojunction and heterojunction. For homojunction devices, both p and n type semiconductors are from the same material whereas in heterojunction devices, the p-n junction is formed from different semiconductor materials.

In general, homojunction solar cells are made from indirect gap semiconductors such as silicon. In these type of cells, the light is absorbed over a distance of 50 to 100 microns. Because the indirect bandgap semiconductors have low absorption coefficients, the absorber layer needs to be thicker (50-300 μm) in these types of cells. For photo-generated carriers to be effectively collected at the junction before they are lost through recombination, the diffusion length of the material has to be higher than 100 μm. Diffusion length is defined as the average distance over which the carriers can travel before they will recombine. In polycrystalline semiconductors, the grain boundaries in a material act as recombination sites. Therefore the diffusion length of the material is limited by the grain size of the material. For obtaining a diffusion length of 100 μm, one requires a single crystal with no grain boundaries or large grain polycrystalline material with grain size greater than 100 μm. Therefore it requires use of crystalline or very large grain polycrystalline material that would have long diffusion lengths (>100 microns). Polycrystalline thin film solar cells are made from direct gap semiconductors.

These semiconductors have high absorption coefficients and absorb the light within a distance of 1-2 microns and thus can tolerate medium grain polycrystalline materials with effective diffusion lengths of approximately two (2) microns. For minimizing the current loss it is essential to keep the p-n junction away from the free surface (or interface) containing a high density of defects called surface states, which are responsible for the loss of photo-generated carriers. Free surface contains broken bonds at surface and an interface between dis-similar materials contains bonding between two types of lattices. The broken bonds and lattice mismatch give rise to electronic defects on the respective surfaces. Again these defects are effective recombination sites for the photo-generated carriers.

These losses necessitate the use of a heterojunction design, incorporating a window layer. The window layer allows the p-n junction in the cell to be located away from the absorber layer of the device. It is well known in the art, that the design and engineering of window layers should have as high a bandgap as possible to minimize absorption losses. The window layer should also be materially compatible with the absorber layer so that the interface at the absorber/window layer would contain negligible interface defect states.

There are two leading candidates for the polycrystalline solar cells based on cadmium telluride (CdTe) and cadmium indium gallium sulfide (CIGS). In both of these cases, cadmium sulfide (CdS) is used as a window has produced the best device performance, proving CdS to be one of the best window materials in heterojunction design. Attempts to use other materials with higher bandgap such as ZnS, CdₓZn₁₋ₓS and ZnSe have been unsuccessful giving devices with lower V_{oc} and fill factors (FF).

One major drawback for CdS is its relatively low bandgap of approximately 2.42 eV. Low bandgap results in current loss in the device due to the absorption of photons with energies higher than 2.42 eV. Photo to dark conductivity ratio for CdS deposited with conventional techniques is also low which implies inferior electronic quality of this material. Photo to dark conductivity ratio is a good measure of electronic quality of the material. As mentioned above, electronic defects are effective recombination centers. Therefore higher photo to dark conductivity ratio means that photo-generated carriers in such a material effectively contribute to the conductivity and are not lost through recombination.

For instance, CdTe is a promising photovoltaic material for low cost thin film solar cells because of its near optimum bandgap of 1.5 eV and its high absorption coefficient. In cadmium telluride/cadmium sulfide (CdTe/CdS) device structures, CdS has been commonly used as a most successful window material. However, the CdS window layer has a lower bandgap (˜2.42 eV) that causes considerable absorption in the short-wavelength region. For the case of CdTe/CdS devices, optical losses in the cell are considered to maximize short circuit current density (J_{sc}) and to minimize the absorption in both front contact transparent conductive oxide (TCO) and the window layer (e.g., CdS). For reducing J_{sc} loss due to window layer absorption, the thickness of this layer is desirably reduced, since optical absorption is an exponential function of layer thickness. Moreover, higher J_{sc} can be achieved by reducing the CdS thickness to improve short wavelength response in conventional CdTe/CdS device structures. However, reducing the CdS thickness can adversely impact device V_{oc} and FF. Therefore, it is desirable within the art to increase window layer bandgap so that it is transparent to a large portion of visible spectrum.

Because of the surface roughness of the underlying TCO, complete coverage of the TCO with a thin CdS (or other window layer material) layer is difficult to obtain. Often incomplete coverage, or “pinholes” in the CdS film, results in direct contact between the TCO and the CdTe, creating localized TCO/CdTe junctions in comparison to a CdTe/CdS junction. Poor junctions in spots parallel to good junctions have a significant influence on the Voc and FF of the device. Hence a thicker CdS layer has to be used in most CdTe module manufacturing processes. Optimizing the efficiency of these PV devices requires the balancing of high V_{oc} and FF, while maintaining higher J_{sc}.

Moreover, adhesion problems of semiconductor materials within the deposition process can limit the optimal production of a multi-layered PV device. For example, a cadmium chloride (CdCl₂) post-treatment is an important process for making high efficiency CdTe devices; however, one of the disadvantages of post-treatment is that over treatment can create a loss of adhesion.

Another related difficulty in producing heterojunction solar cells that have limited their energy conversion efficiency is the process or manufacturing limitations. Present material science and process manufacturing limitations have traditionally burdened the advancement of window layer and CdTe/CdS development. Within the art, increased oxygen concentration in the window layer, such as the CdS layer, has been attempted but has not achieved conversion efficiencies above nine percent (9%). Prior knowledge of the benefits of higher oxygen concentration in window layers has been limited. Moreover, current deposition techniques are not capable of producing high oxygen concentration in the window layer.

The window layer can be prepared by several deposition methods, such as Chemical Bath Deposition (“CBD”), Close-Spaced Sublimation (“CSS”), and Sputtering. Each of these deposition methods has its advantages and disadvantages. For example, the primary advantages of CBD are the simplification of the process and its ease for small area devices. However, at larger scales, CBD the process has a low deposition rate and it generates large amounts of liquid waste. The low deposition rates and the treatment of waste liquid solution increase the manufacturing costs. CBD processes are also plagued with higher rates of impurity and defect densities. These resultant non-uniform CBD depositions adversely impact the production yield of PV devices. Although CBD produced CdS layers contain some oxygen (typically, less than 10 at. % concentration), the bandgap of CdS remains the same for the window layer.

In CSS, process advantages are the ease of scale-up, high deposition rates, and efficient material utilization. However, a number of problems are associated with CSS which include, CSS consumes a large amount of energy, since deposition occurs at high temperatures; and these high temperatures (generally 550 to 600 degrees Celsius) typically generate large grain size. CdS films deposited with large grain size commonly contain pinholes when prepared at small thicknesses which impact the device's V_{oc} and FF. Although adverse effects of large grain size (typically 0.5 to 1 micron) can be countered with deposition of thicker layers, energy conversion efficiencies are profoundly impacted with increased window layer thickness. CdTe PV modules with thicker CSS-CdS layers have resulted in J_{sc} of about 18 mA/cm² and a J_{sc}, which impairs energy conversion efficiency. Furthermore, high temperatures in sublimation processes contribute to poor interdiffusion, and normal bandgaps (typically equal to or less than 2.42 eV) and result in CdTe module energy conversions less than ten percent (10%). Therefore, sublimation processes failed to produce window layers having high oxygen content.

Additionally, CSS deposition problems also include the difficulty of managing a dynamic process. Ideally for production, the chosen deposition process should incorporate parameters that can be easily maintained, such as controlling the source material, deposition rates and the chamber environment. The inability to control or predict production parameters impairs production yields. In general, a CSS deposition process using a CdS source encounters problems associated with controlling the source since the CdS composition changes during the deposition process. More specifically, the CdS source oxidizes during the CSS process in a gas mixture composed of an inert gas and oxygen, adversely affecting the yield and reproducibility of the process.

Sputtered processes for thin film deposition offer many manufacturing advantages. Sputtering techniques include, but are not limited to, RF sputtering (both with and without magnetron sputtering), direct current (DC) sputtering, triode sputtering, and ion-beam sputtering. The ease of scale up, control of deposition rates, lower impurity and defect densities, and better control of film thickness and uniformity are known advantages of sputtering. However, sputtered CdS films suffer from poor understandings of underlying scientific material science and PV design issues, such as the need to use thicker film (greater than 2000 Angstroms) to maintain high V_{oc} (greater than 800 millivolts), and the effect of low J_{sc} caused by stronger interdiffusion between sputtered CdS and CdTe films. Current successes using sputtered techniques for CdS films have resulted in PV device energy conversion efficiencies of less than 12 percent with less than optimal V_{oc}, J_{sc}, and FF.

### SUMMARY OF THE INVENTION

Accordingly, the method and apparatus of the present invention provides a more efficient, heterojunction photovoltaic device than has previously been available. In one aspect of the present invention, a high efficiency PV device is provided wherein the window layer of the cell is fabricated to contain a greater concentration of oxygen resultant from the deposition method. Window layers contemplated by the present invention include cadmium sulfide (CdS) and various alloys of zinc cadmium sulfide (ZnₓCd₁₋ₓS). Layer deposition methods of the present invention are based on introducing oxygen into the deposition process to increase the oxygen concentration of the deposited window layer. Increased oxygen concentration in the window layer contributes to the PV device's efficiency by increasing window layer bandgap and improving J_{sc}.

In another aspect of the present invention, a PV device having lower impurities and defect densities is provided. The present invention provides a PV device and method that balances and optimizes high J_{sc}, V_{oc}, and FF in energy conversion devices. Advantages of the present invention include, but are not limited to, a deposition method that operates at about room temperature; an energy conversion device having increased oxygen concentration in the window layer which further results in a higher optical bandgap, a better photo to dark conductivity ratio, increased current density, and greater efficiency; and a method for having high reproducibility and processing yields, and other related benefits to the PV industry.

A further aspect of the present invention is to provide a physical deposition method that facilitates better controlled deposition rates, promotes greater control of film thickness and uniformity, and allows ease of scale up while maintaining large yields. Still further, an aspect of the invention is to provide an enhanced deposition method that promotes greater control of the deposition process and source material, while further advancing the ability to incorporate increased oxygen concentration in the window layer. In a related aspect of the invention, a deposition method at about room temperature is provided that includes a means to introduce and optimize oxygen concentration within the window layer.

Additional aspects, advantages, and novel features of the invention shall be set forth in part of the description that follows, and in part will become apparent to those skilled in the art upon examination of the following or may be learned by the practice of the invention. The advantages may be realized and obtained by means of the instrumentalities and in combinations particularly pointed out in the appended claims. To achieve the foregoing and the other aspects of the invention and in accordance with the purposes of the present invention, each embodiment of the heterojunction, photovoltaic device comprises at least semiconductive layers deposited on a substrate or other layers where specific layers, such as window layers, are deposited using a deposition technique, such as RF sputtering, that incorporates a gas mixture of an inert gas with oxygen during the deposition process. Incorporation of an inert gas/O₂ fluid mixture increases the oxygen concentration within the window layer.

This invention results from the realization that the difficulty of improving energy conversion efficiencies in heterojunction PV devices is caused by deposition methods which inadequately control the source material and deposition process. These resultant films have impurities, poorly bonded oxygen, low oxygen content, and large grains requiring thicker layers. These shortcomings can be eliminated by a deposition method which deposits at or near room temperature in a mixture of inert gas and oxygen, which results in higher oxygen concentrations in the deposited film thereby providing higher optical band gap and photo to dark conductivity ratio, and promoting higher energy conversion efficiencies of the PV device. Increased oxygen concentration within the window layer enhances the PV cell's conversion efficiency. Higher optical band gaps are achieved with the increased concentration of oxygen within the deposited film.

These and various other features as well as advantages which characterize the present invention will be apparent from a reading of the following detailed description and a review of the associated drawings.

### BRIEF DESCRIPTION OF THE DRAWINGS

FIG. 1 is a block diagram of an embodiment of the present invention.

FIG. 2 is a block diagram of another embodiment of the present invention.

FIG. 3 is schematic of a radio frequency sputtering system used in an embodiment of the present invention.

FIG. 4 is a side elevation view in a schematic of an embodiment of a heterojunction photovoltaic energy conversion device incorporating the present invention within the window layer.

FIG. 5 is a side elevation view in a schematic of a different embodiment of a heterojunction photovoltaic energy conversion device incorporating the present invention within a different window layer design.

FIG. 6 is a plot of transmittance (T) of an embodiment of the present invention.

FIG. 7 is a plot of X-ray diffraction patterns of an embodiment of the present invention.

FIG. 8 is a plot of a current-voltage (I-V) curve of an embodiment of the present invention.

FIG. 9 is a plot of quantum efficiency (QE) data of an embodiment of the present invention.

### DETAILED DESCRIPTION

Definitions:

The following definitions are provided to facilitate understanding of certain terms used frequently herein and are not meant to limit the scope of the present disclosure:

The term “about” used herein refers to a tolerance of plus or minus ten percent (+/−10%) of the value or quantity modified by the term.

Inert gas includes gases that lack reactivity, such as, but not limited to, stable gases such as noble gases and nitrogen (N₂) and mixtures thereof, including inert nitrogen compounds.

Room temperature generally describes temperatures ranging from about twenty degrees Celsius (20° C.) to about thirty degrees Celsius (30° C.).

Atomic percent used herein is abbreviated as (at. %)

Photoconductivity (σ_{L}) is measured under illumination of 100 mW/cm².

Dark photoconductivity (σ_{D}) is measured in the absence of light (in the dark).

Oxygen concentration within a deposited layer is measured by X-ray photoelectron spectroscopy (XPS) in atomic percent (at. %).

Gas mixture used herein is a composition of gases comprising oxygen and an inert gas or mixtures thereof, wherein the percentages of oxygen in the gas mixture is about 1% to about 5% by volume. Hence, a gas mixture containing 5% oxygen refers to 1 part oxygen and 20 parts of other gas or gases by volume. The present invention envisions that small or negligible amounts of contaminants may be present in the invention environment, as long as the contaminants do not inhibit the incorporation of oxygen in the deposited layer. Contaminants include stray or undesirable gases or fluids present from leaks, imperfect vacuums, or the like within the deposition environment.

Common PV design factors and definitions: V_{oc}, J_{sc}, and FF. V_{oc} refers to the voltage developed by the solar cell, under illumination, in open circuit condition. Open circuit typically means that the cell is connected to an infinite resistance load so as to produce no current. In practice, V_{oc} is commonly measured with a voltmeter with very high input impedance. The V_{oc} parameter determines the maximum voltage a given cell can produce. J_{sc} refers to the current developed by the cell, under illumination, in a short circuit condition. Short circuit means that the cell is connected to load with zero resistance, for the case when the cell generates no voltage. Within the art, J_{sc} is commonly measured with an amp meter with very low input impedance connected to the terminals of cells.

Solar PV development and design is primarily focused on the amount of power a PV device can generate. As V_{oc} and J_{sc} are the maximum voltage and maximum current that can be generated by a given cell, the theoretical maximum power that a cell could possibly generate is a product of V_{oc} and J_{sc}, since electrical power is the product of current and voltage. In reality, the maximum current and maximum voltage for the maximum power lies in region between V_{oc} and J_{sc} when the cell is connected to different loads. Within the art, these parameters are measured during this sweep of varying loads, producing the power generated by the cell at each point, which in turn, determines a point where this product (or power) is a maximum. This point is referred to as maximum power point and corresponding parameters are called Vₘₚ and Jₘₚ. The fill factor is then defined as FF=(Jₘₚ×Vₘₚ)/(J_{sc}×V_{oc}).

To produce maximum power, all three factors are ideally maximized for PV design. These factors also affect the wavelength region that is absorbed by the cell and the charge carrier movement within the cell layers, affecting the total area energy conversion efficiency of the photovoltaic device. Materials deposited or formed on various layers of a PV device require the balancing and optimization of these factors.

The efficiency of a cell or PV device may be determined, typically within the art, by the equation: efficiency=(J_{sc}×V_{oc}×FF/Incident power)×100%.

Modes and Embodiments of the Present Invention:

This invention results from the realization that the difficulty of improving energy conversion efficiencies in heterojunction PV devices is caused by deposition methods which inadequately control the source material and deposition process which further result in window layers having impurities, poorly bonded oxygen, low oxygen content, normal bandgap, and large grain size which requires thicker layers. Window layers contemplated by the present invention include cadmium sulfide (CdS) and various alloys of zinc cadmium sulfide (ZnₓCd₁₋ₓS). These shortcomings can be minimized by a deposition method, which deposits at about room temperature and in a mixture of inert gas and oxygen which results in higher oxygen concentrations in the CdS film. Higher oxygen concentration provides window layers with higher optical band gap and photo to dark conductivity ratio and promotes higher energy conversion efficiencies of the PV device.

In an embodiment of the present invention, a semiconductor deposition method is presented, which further enhances a PV device's efficiency. The deposition method includes a controlled gas mixture to increase oxygen in the deposited window layer. The deposition method also includes one or more deposition chambers for introducing a gas mixture at a pre-determined ratio of inert gas to oxygen. The ratio may be determined and controlled by various means within the art, including, but not limited to, ex-situ and in-situ methods, but is commonly performed by mass flow rate within the chamber. Within the present invention, the gas mixture is introduced in the chamber after the chamber has been loaded with a substrate and a target material for depositing on the substrate. An energy source is applied to the target material in the presence of the gas mixture, causing the target material to transfer to the substrate, with an increased oxygen concentration.

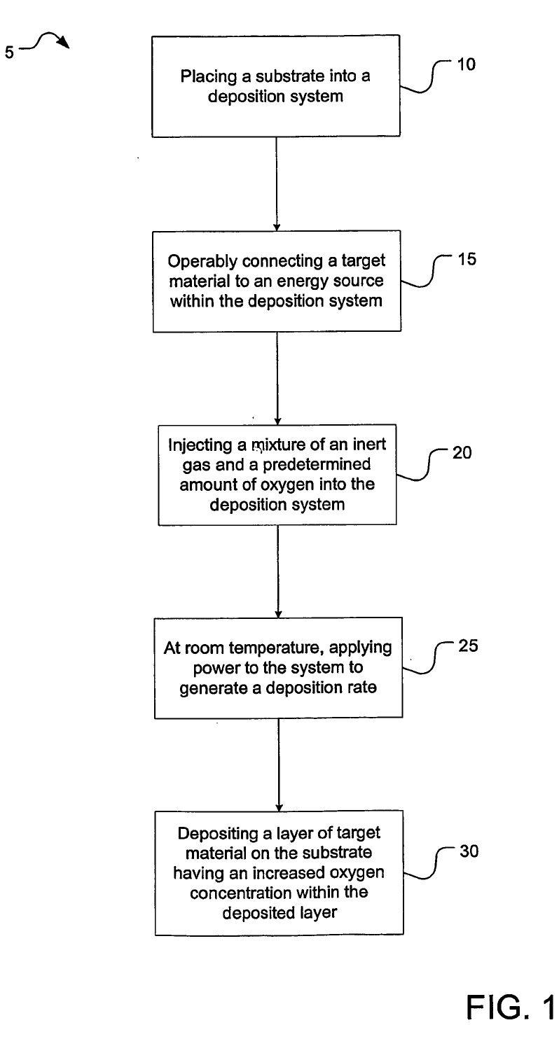

FIG. 1 represents a flow diagram of an embodiment of the present invention. Deposition process 5 includes step 10, a step of placing or affixing a substrate into a deposition system, usually a chamber. In Step 15, a target material is connected to a deposition system energy source. The target material is a semiconductor material desired to be physically deposited on the substrate. In Step 20, a predetermined ratio of oxygen to inert gas is injected into the deposition system. Within the present method, the percent of oxygen can be varied between one to five percent (1-5%) oxygen by volume of the gas mixture. In Step 25, the deposition system is operated at room temperature (about 20-30 degrees Celsius), which further generates a deposition rate. In Step 30, the deposition of a layer of target material having a high concentration of oxygen on the substrate or superstrate is accomplished. The resultant deposited layer has enhanced photo to dark conductivity ratio and an increased bandgap.

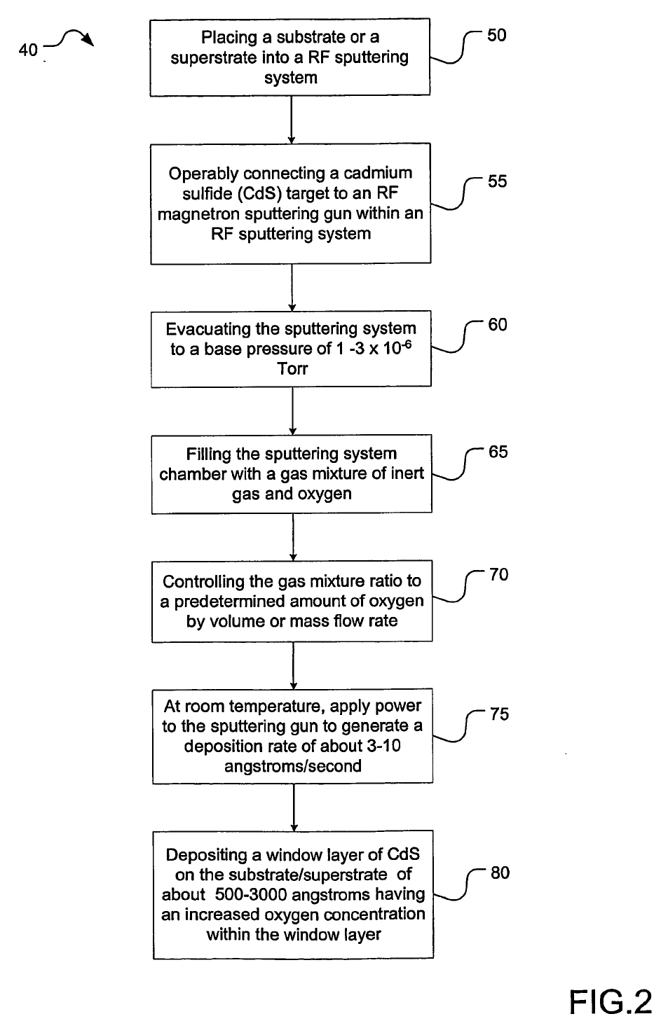

FIG. 2 represents an alternative flow diagram of an embodiment of the present invention. Deposition process 40 includes step 50, a step of placing a substrate into a radio frequency (RF) sputtering system. In general, a substrate is made of a Transparent Conductive Oxide (TCO)-coated glass or a semiconductor material having back contact. In Step 55, a cadmium sulfide target material is connected to the sputtering system energy source, e.g., an RF magnetron sputtering gun. In some cases, the target material is an alloy of zinc cadmium sulfide represented by the formula ZnₓCd₁₋ₓS. In Step 60, a vacuum is pulled within the sputtering system to a base pressure of about 1-3×10⁻⁶ Torr, although lower vacuum pressures are envisioned within the scope of the present invention. In Step 65, the gas mixture of an inert gas and oxygen is injected into the deposition system. Typically any noble gas or nitrogen (N₂) can be used as the inert gas. In preferred embodiments, Argon is commonly used as the inert gas. In Step 70 the oxygen to inert gas ratio is controlled either by volume or by mass flow, to a predetermined level. Within the present method, the percent of oxygen can be varied between one to five percent (1-5%) oxygen by volume of the inert mixture. In Step 75 the deposition system is operated at room temperature (about 20-30 degrees Celsius), which further generates a deposition rate. Deposition rates desirable in an RF sputtering system are about three to ten angstroms per second (3-10 Å/sec). In Step 80, a window layer of the chosen target material is deposited having a high concentration of oxygen within the layer, possessing a greater photo to dark conductivity ratio and optical bandgap properties. The window layer is typically deposited at thicknesses of 500-3000 angstroms (Å).

Thin film semiconductor heterojunction photovoltaic devices can be produced by a variety of deposition techniques. Embodiments of the present invention, having deposited layers with high oxygen concentration, can be produced by a variety of deposition techniques. Sputtering deposition techniques, such as direct current sputtering, radio frequency (RF) sputtering (both with and without magnetron sputtering), triode sputtering, and ion-beam sputtering. RF sputtering has proven to be the most dynamic and has shown the greatest amount of success of the present invention. However, other deposition techniques can be-adapted within the spirit of the invention to incorporate an improved deposition method and an improved oxygen concentration within the deposited layer. Such techniques that can be used include, but are not limited to, laser ablation at low temperature, ion assisted physical vapor deposition, and vapor transport deposition (VTD). Although the present invention contemplates adaptation in the enumerated examples above, it is to be understood that the invention includes other processes.

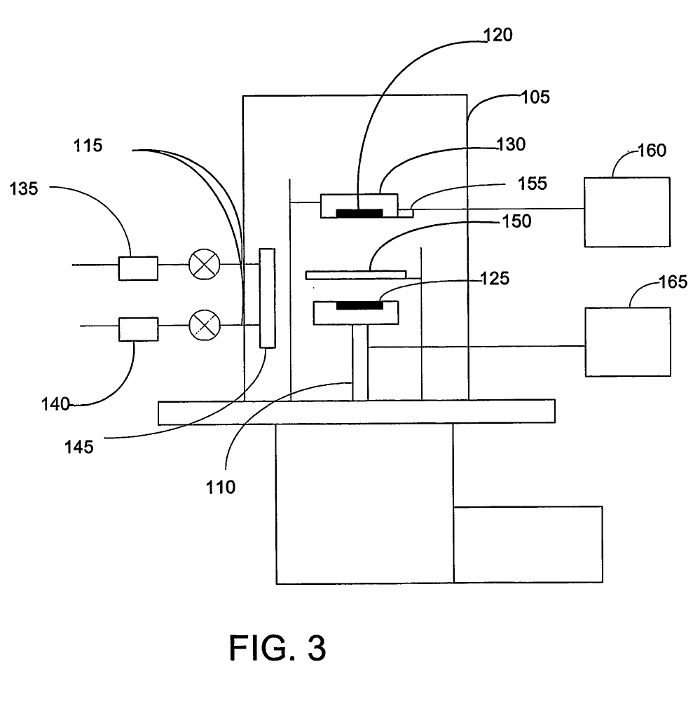

An embodiment of the present invention employs an RF sputtering technique, as shown in FIG. 3. The RF sputtering technique includes using a method of fabricating a semiconductor heterojunction photovoltaic device. The photovoltaic device uses a sputtering system 100, which includes a chamber 105 with an energy source 110, and gas inlets 115, each connected to the chamber 105. The gas inlets 115 are used to inject gas into the chamber 105 and the chamber 105 is used to control the deposition environment. Typically, the energy source 110 is a sputtering gun used in an RF sputtering system.

Within the present invention, prior to the deposition process or the initiation of the sputtering system, the chamber 105 is loaded with a substrate 120 and a target material 125. Substrates 120 can be transparent conductive oxide (TCO) film on glass substrate or glass substrates such as the Corning 7059 substrate. The TCO films within the present invention may include substrates containing various, existing deposited layers of semiconductor material. These substrates are typically fixed to a holder 130 within the chamber 105; however, substrates 120 may be oriented and affixed by a variety of means.

Within the present invention, substrates may be placed at predetermined distances from the target material 125. A solid slab is typically placed in the sputter gun, commonly referred to as a target, which is the desired film material to be deposited. The target material 125 is placed at a pre-determined distance and orientation from the substrate 120. The distance between the substrate 120 and the target 125 can be varied from about six centimeters (6 cm.) to about nine centimeters (9 cm.). Target material 125 maybe any semiconductor material possessing the requisite properties for the selected deposition method. In heterojunction PV design, the target 125 is typically cadmium sulfide (CdS) or alloys of zinc cadmium sulfide (ZnₓCd₁₋ₓS), but can be other semiconductor material for the characteristics designed within the PV device. The target 125 is operably connected to the sputter gun 110 within the sputtering system 100.

Once the chamber 105 is loaded with the desired substrate 120 and target material 125, the pressure within the chamber 105 is pumped down to a base pressure, to about 1×10⁻⁶ Torr to about 3×10⁻⁶ Torr, but can be pumped down to pressures less than the 1×10⁻⁶ Torr range.

A gas mixture comprised of an inert gas 135 and oxygen 140 is introduced into the chamber 105. Possible inert gases available for use within the present invention include noble gases and nitrogen (N₂); note that argon gas is commonly used within sputtering systems. The gas mixture of the present invention can be controlled and monitored by a variety of means. For example, the mixing of the inert gas with oxygen may be combined and mixed prior to entering the chamber, or conversely, mixed upon entering the chamber with the aid of a gas distributor 145. Measurement, characterization, and control of the gas mixture may be performed externally or internally by utilizing numerous techniques commonly known within the art. In some cases the mixture of oxygen with an inert gas is measured by mass flow rate to obtain critical features of the invention.

Different percentages of oxygen in the gas mixture can range from about 1% to about 5% oxygen. These percentages are typically controlled by a mass flow meter, but it is well known in the art that gas composition and gas characteristics can be measured and controlled by numerous techniques. Once the gas mixture is introduced into the chamber, the partial pressure of the oxygen/inert gas mixture should be maintained between about 10×10⁻³ Torr to about 20×10⁻³ Torr.

Selection of a sputtering power is dependent upon substrate size and deposition rate. Manipulating various parameters provides a range of deposition rates. In an embodiment of the present invention, where the partial pressure ranges from 10 to 20×10⁻³ Torr and the radio frequency sputtering power ranging from between about 50 and about 70 watts, a deposition rate of about 3 angstroms per second to about 10 angstroms per second is obtained.

In another embodiment of the present invention, a shutter 150 is used as a temporary or removable shield to protect the substrate 120 during a pre-sputtering routine. In the pre-sputtering routine, the shutter is orientated as a barrier while the target material 125 is sputtered for about five (5) minutes. The shutter 150 prevents actual deposition to the substrate 120 during this routine. Pre-sputtering enhances reproducibility of the deposition process and deposited layer quality.

Within the present invention, the sputter gun 110 is applied to the target material 125 to deposit a layer of target material 125 on the substrate 120 during the operation of the sputtering system at room temperature. The present invention contemplates chamber temperatures in excess of room temperature due to the energy source's thermal contribution. Such method generates a material having an increased concentration of oxygen within the CdS layer. During the deposition process, substrate temperature can be monitored with temperature readout device 155. Similarly, deposition thickness can be monitored and controlled via a quartz crystal monitor 160. Controlling and monitoring power supply within the chamber 105 is further accomplished by a RF matching network and power supply 165, which aids in the coordination of system parameters, such as power, temperature, pressure, ambient, and deposition thickness.

Sputtering systems provide the ability to control and monitor many deposition parameters. Since the control of film deposition may be improved by balancing numerous parameters, such as the pressure, atmosphere and temperature, the energy source used, and the size and characteristics of the target material, as well as the orientation and location of the target material within the chamber, sputtering systems therefore provide an ideal deposition system for the present invention. For example, clean and dry inert gas contributes to maintaining the deposited composition characteristics, and low moisture is typically required to prevent unwanted oxidation of the deposited film. However, control of the amount of the gas mixture entering the tank chamber is important due to its effect of raising the pressure in the chamber. Within the present invention, the gas mixture containing oxygen is important to the integration of increased oxygen concentration within the deposited layer.

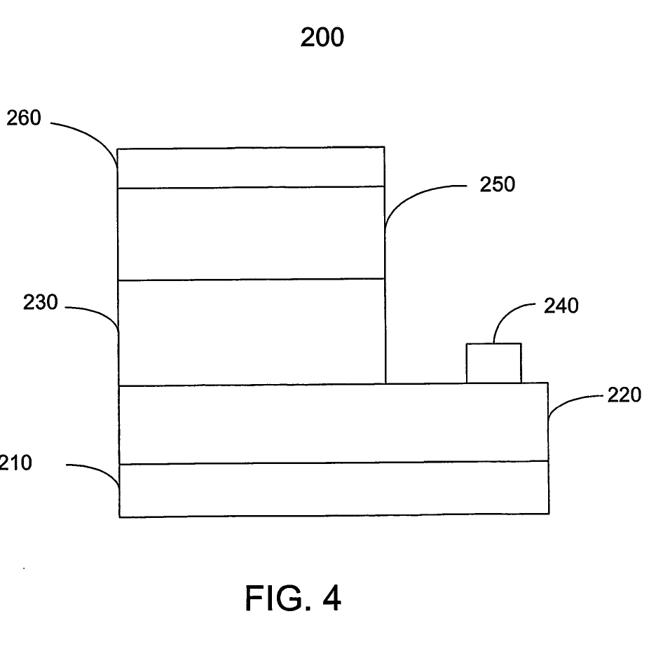

Energy conversion devices produced by the present invention result in a window layer having a higher concentration of oxygen with improved optical bandgap and photoconductivity. FIG. 4, illustrates a heterojunction photovoltaic energy conversion device 200 manufactured using methods of the present invention. Substrate 210 is a foundation structure for making device 200. Front contact 220 is a transparent conductive layer, with electrical tap 240. Window layer 230 is made of cadmium sulfide (CdS) or an alloy of zinc cadmium sulfide (ZnₓCd₁₋ₓS). Within the present invention window layer 230 has concentrations of oxygen of about fourteen percent (14 at. %) to about twenty-three (23 at. %) atomic percent. Depositions are performed in a gas mixture of about one percent (1%) oxygen to about five percent (5%). Absorber layer 250 is typically made of cadmium telluride (CdTe) within device 200. Back contact 260 is provided to complete the circuit for energy conversion.

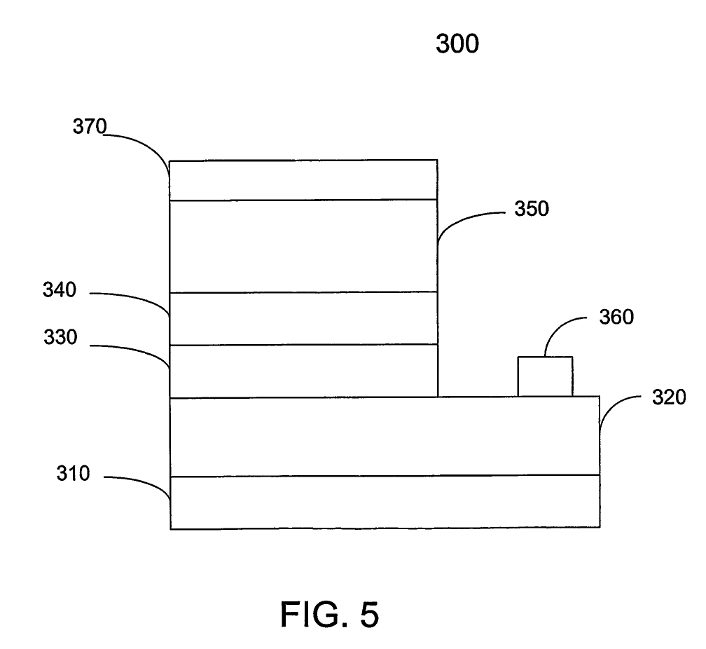

FIG. 5 illustrates an alternative energy conversion device 300 having a glass substrate 310, with front and back electrical contacts 320 and 370, respectively. Front contact 320 is a cadmium stannate (Cd₂SnO₄, or CTO) layer coupled with a buffer layer 330, typically formed using zinc stannate (Zn₂SnO₄, or ZTO). Together front contact 320 and buffer layer 330 form a CTO/ZTO stack, to be used as a superstrate for advancing PV design and performance. Window layer 340 is deposited using the present invention method, resulting in a window layer having high oxygen concentration and improved optical bandgap and photoconductivity. Window layer 340 is also made of cadmium sulfide (CdS) or an alloy of zinc cadmium sulfide (ZnₓCd₁₋ₓS). Within the present invention window layer 340 has concentrations of oxygen ranging from about fourteen percent 14 at. % for depositions performed in a gas mixture of about three percent (3%) oxygen and twenty three percent (23 at. %) oxygen concentration for depositions operated in a gas mixture environment having five percent oxygen (5%).

Varying deposition systems parameters, and more particularly, varying oxygen to inert gas ratios from about 1% to about 5% results in material depositions containing high oxygen concentration. The resulting depositions and their respective material properties and characterizations are shown in Table 1, wherein the electrical properties of sputtered films at different oxygen-argon ratios are presented.

TABLE 1
Electrical properties of sputtered CdS films
at different O₂/Ar ratios

| | O₂/Ar | σ_{D} | σ_{L} | |
|---|---|---|---|---|
| Sample # | (%) | (1/(Ωcm) | (1/(Ωcm) | σ_{L}/σ_{D} |
| S-203 | 0 | 8.2 × 10⁻⁷ | 2.8 × 10⁻⁵ | 34 |
| S-204 | 1 | 2.2 × 10⁻⁸ | 8.3 × 10⁻⁶ | 377 |
| S-205 | 2 | 2.7 × 10⁻⁹ | 2.6 × 10⁻⁶ | 963 |
| S-206 | 3 | 6.3 × 10⁻¹⁰ | 6.3 × 10⁻⁷ | 1000 |
| S-207 | 5 | 4.0 × 10⁻⁹ | 1.2 × 10⁻⁷ | 30 |

Table 1 is representative of sputtered cadmium sulfide films deposited at different oxygen to argon ratios. The oxygen to argon ratio was varied from 0% to 5% using various samples of substrates for depositing cadmium sulfide (CdS) films. As can be seen within Table 1, oxygen to argon ratios of about 2% to about 3% resulted in increased photo to dark conductivity ratio. For the case of depositing cadmium sulfide film as a window layer in an inert gas environment in the absence of oxygen, the photo to dark conductivity ratio produced was 37, whereas the addition of oxygen to about 3% increased the ratio by a factor of more than twenty (20). This increased electrical property of sputtered films contributes to the advancement and improvement of efficiencies within photovoltaic devices, and more specifically, to thin film semiconductor heterojunction photovoltaic devices. Electrical property measurement was made using the Keithley 6517A electrometer.

Similarly, in Table 2, optical properties are also enhanced by monitoring and controlling the gas mixture of an inert gas and oxygen.

TABLE 2
Optical bandgap of sputter CdS film at different O₂/Ar ratios

| | O₂/Ar | Optical bandgap |
|---|---|---|
| Sample # | (%) | (eV) |
| S-203 | 0 | 2.42 |
| S-204 | 1 | 2.52 |
| S-205 | 2 | 2.65 |
| S-206 | 3 | 2.80 |
| S-207 | 5 | 3.17 |

Specifically, Table 2 represents optical band gap data of sputtered cadmium sulfide films deposited at different oxygen and argon ratios, where the oxygen and argon ratios are again varied between about 1% and about 5% oxygen within the gas mixture. Optical band gap measured in electron volts increases with an increase of the oxygen to argon ratio. In particular, optical band gaps, in absence of oxygen, with sputtered CdS films using solely argon result in optical band gaps of approximately 2.42 to about 2.48 electron volts. However, increasing oxygen and argon ratios result in an improved optical band gap, that range from approximately to 2.52 electron volts to as high as 3.17 electron volts. A Cary 5 spectrophotometer was used for the optical property measurement.

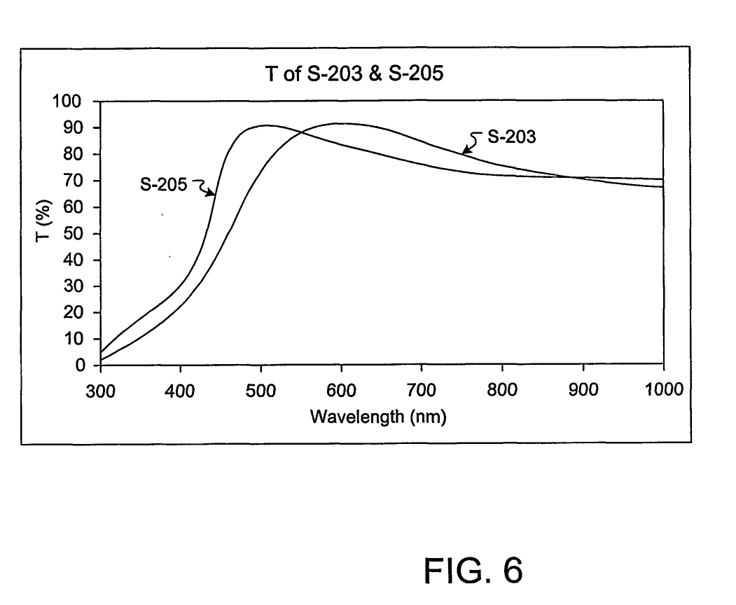

Additional characterization of the resultant deposition and its associated photovoltaic device include the transmittance of sputtered cadmium sulfide films where the transmittance shifts to a shorter wavelength, which can greatly help improve the device's short circuit current density and efficiency as can be seen in FIG. 6. FIG. 6 is representative of transmittance of two sputtered cadmium sulfide films deposited in pure argon and 2% oxygen to argon ratio at ambient temperature, sample label S-205 shows a shift to shorter wavelength as opposed to a pure argon deposition represented by sample S-203, where the wavelength and transmittance is shifted to the right. Further analysis of the CdS films include compositional and structure analysis using various measuring techniques, such as X-Ray diffraction (XRD), X-Ray photoemissions spectroscopy (XPS), and atomic force microscopy (AFM). Table 3 represents deduced atomic concentrations of sputtered cadmium sulfide films deposited at different oxygen to argon ratios.

TABLE 3
Atomic concentrations of oxygen within sputter
CdS film at different O₂/Ar ratios

| Sample # | O₂/Ar (%) | O (at. %) |
|---|---|---|
| S-203 | 0 | 4.35 |
| S-204 | 1 | 8.66 |
| S-205 | 2 | 11.08 |
| S-206 | 3 | 13.88 |
| S-207 | 5 | 22.73 |

Table 3 further represents deduced concentrations of oxygen within the window layer based upon X-ray photoemission spectroscopy (XPS). Sputtered samples in the absence of oxygen using pure argon at ambient pressure resulted in oxygen concentrations of about 4.35 at. %. Substrates prepared with an embodiment of the present invention using sputtered CdS films in an oxygen-argon mixture of gas within the sputtered system chamber results in increased oxygen concentration within the deposited layer once oxygen to argon ratios are increased. For example, samples prepared in a 3% oxygen to argon mixture ratio resulted in oxygen concentration in the deposited layer of about 13.88 at. %, samples prepared in a 5% oxygen to argon ratio resulted in oxygen concentrations as high as about 22.73 at. %. Higher oxygen concentration in comparison of chemical bath depositions of CdS films and closed space sublimation CdS films result in higher optical band gaps and photo to dark conductivity ratio than films deposited in pure argon or other inert gases. Once CdS films are integrated into cadmium telluride devices, higher short circuit current density can be demonstrated. The integrated and resultant cadmium telluride cell has a proven total area efficiency of greater than 15% using sputtered CdS films with higher oxygen concentrations.

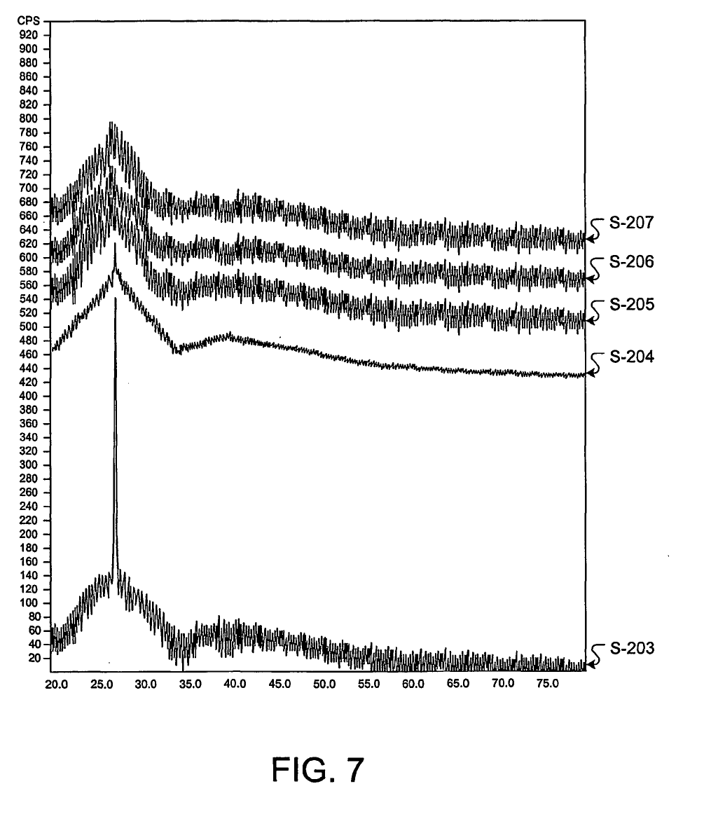

Compositional analysis such as X-Ray diffraction show patterns of sputtered cadmium sulfide films deposited at different oxygen to argon ratios as shown in FIG. 7, CdS films deposited in pure argon, such as sample S-203, exhibit preferential orientation along the 002 axis. The intensity of the 002 peak is reduced with the increase of the oxygen to argon ratio, as in sample S-204. However, this intensity disappears when the oxygen to argon ratio increases to 2% or more. The sputtered CdS films, as in samples S-205 through S-207, deposited at more than 2% oxygen to argon ratio have amorphous structures, thereby showing that addition of oxygen to the deposited layer reduced the grain size of the film.

Compositional analysis and data from atomic force microscopy (AFM), includes data that interprets grain size and surface roughness of deposited layers. AFM micrographs on the surfaces of two sputtered cadmium sulfide films, samples S-203 and S-205, deposited in pure argon and 2% oxygen argon mix, respectively. The film deposited in pure argon has a grain size of about a few hundred angstroms, and an average surface roughness of about 15 angstroms. In contrast, the film deposited in a 2% oxygen-argon mixture demonstrates amorphous structure and has extreme smooth surface with an average surface roughness of about 3 angstroms, again showing that the addition of oxygen aids the design parameters of a PV device layer.

Another illustration of how increased oxygen content in the deposited layer enhances PV device function is shown in Table 4.

TABLE 4
I-V data of two sets of CdTe cells with
different sputtered CdS film

| | V_{oc} | J_{sc} | FF | Efficiency |
|---|---|---|---|---|
| Cell # | (mV) | mA/cm² | (%) | (%) |
| W577-A | 822.5 | 23.84 | 73.11 | 14.33 |
| W577-B | 811.1 | 24.14 | 72.58 | 14.21 |
| W580-B | 829.2 | 24.91 | 70.95 | 14.65 |
| W580-C | 826.9 | 25.25 | 69.85 | 14.58 |

Two sets of cadmium telluride cells were prepared for demonstrating the application of the modified sputtered-CdS film. All cells have a transparent conductive cadmium stannate (Cd₂SnO₄, or CTO) layer and a zinc stannate (Zn₂SnO₄, or ZTO) buffer layer. Device set (W577-A & W577-B) used sputtered CdS film deposited in pure argon, and device set (W580-B & W580-C) used sputtered CdS film deposited in two percent (2%) oxygen/argon ambient. Table 4 represents cadmium telluride (CdTe) device performances using sputtered CdS films deposited in pure argon and another set of cells having sputtered CdS deposited in an oxygen and argon mix of gas. CdTe cells using sputtered CdS films with higher oxygen concentration compared to CdTe cells using sputtered CdS films in pure argon in absence of oxygen resulted in higher short circuit current densities of about 1 milliamp per square centimeters (mA/cm²) higher. Comparatively, current-voltage (I-V) curves of a CdTe cell using a sputtered CdS film with higher oxygen concentration results in improved open circuit voltages and improved short circuit current densities. These results again illustrate the effectiveness of the present invention at increasing oxygen in the deposition layers.

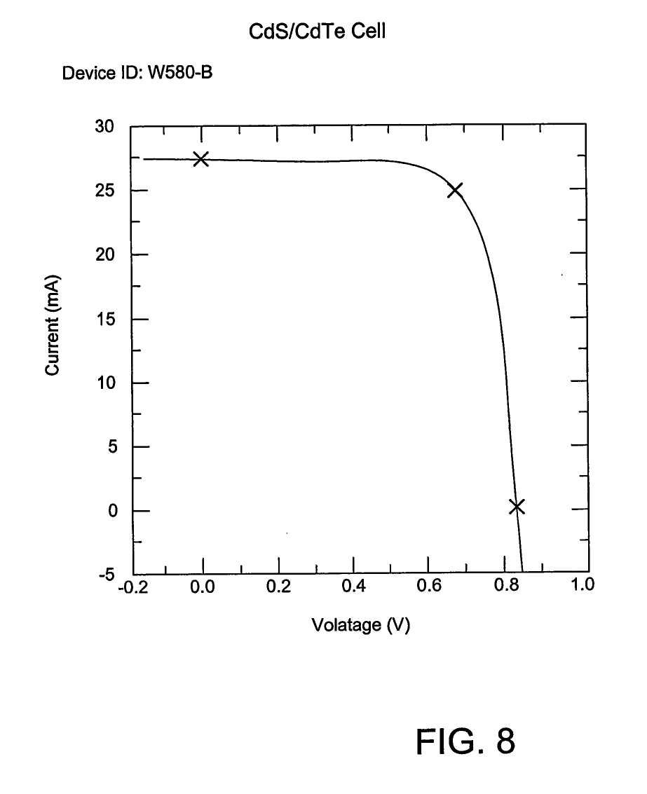

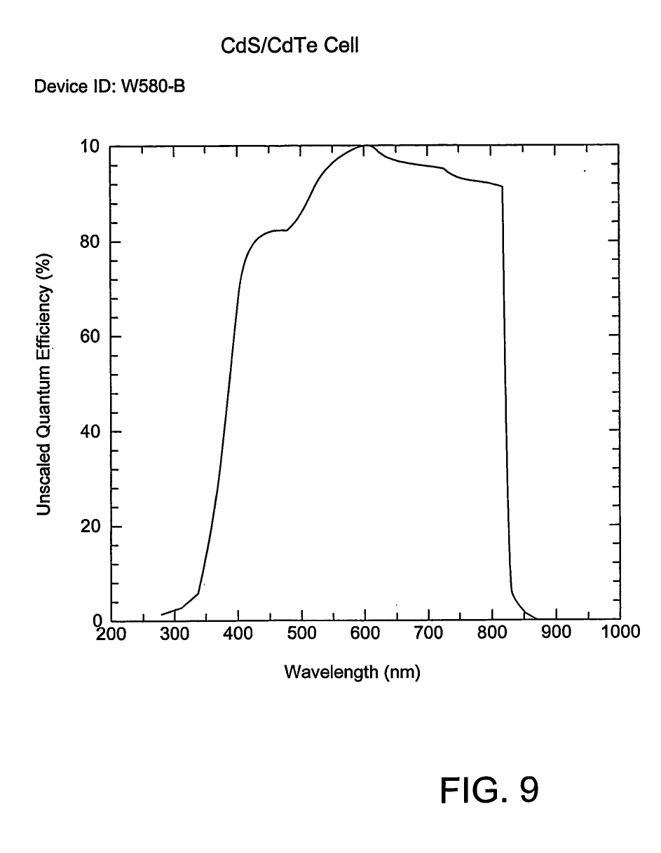

FIG. 8 and FIG. 9 show the current-voltage (I-V) curve and the quantum efficiency (QE) of a CdTe cell having a sputtered-CdS film with higher oxygen concentration, respectfully. FIG. 8 demonstrates a cell total area efficiency of 15.4% and high current density of 25.85 mA/cm². From FIG. 9, the resultant cell has high quantum efficiency at the short-wavelength region, which further results from the cell having a sputtered-CdS window layer with a higher bandgap. These photovoltaic design factors translate into high cell efficiency and illustrate the effectiveness of the present invention at increasing the oxygen concentration in the window layer.

In yet another embodiment of the present invention, magnetron sputtering systems can be used with both radio frequency and direct current sputtering to prepare increased oxygen concentration in the window layers. Magnetron sputtering resolves problems associated with electrons that escape into the chamber that do not contribute to the setting up of the plasma necessary for deposition. In magnetron sputtering systems, magnets behind and around the target are used to capture and/or confine the electrons to the front of the target. Magnetron sputtering systems are more efficient for increased deposition rates. The resulting density of ionized argon atoms hitting the target is increased by an order of magnitude over conventional radio frequency and direct current sputtering systems. Moreover, another benefit of magnetron sputtering systems is a system parameter benefit of lowering the pressure required in the chamber, which contributes to a cleaner deposited film and a lower target temperature.

In an embodiment of the present invention, oxygen is incorporated into deposited layers by the method discussed above. Production level sputtering systems come in a variety of designs. Chambers are either batch systems or single wafer inline designs. Most production machines have load-lock capabilities. A load-lock is an antechamber where a partial vacuum is created so that the deposition chamber can be maintained at vacuum. The advantage of load-lock is a higher production rate. Production machines are usually dedicated to one or two target materials while development machines have a wider range of capability.

The present invention applies, but is not limited to, window layers within solar cells, such as cadmium sulfide (CdS) or alloys of zinc cadmium sulfide (ZnₓCd₁₋ₓS), but can easily be adapted to other semiconductor materials where increased oxygen concentration in the deposited layer is desired for specific design parameters and resultant device benefits. In addition to applicability to various layers and PV devices, the present invention applies to deposition materials in Group II and VI. The breadth of possible compounds within these groups provides advantages in the design and manufacturing of special devices, such as PV devices where band gap engineering is one of many factors essential to performance.

For applications that include window layers within solar cells, absorber layers include cadmium telluride (CdTe), copper indium selenide (CuInSe₂), copper indium gallium selenide alloys (CuIn_{X}Ga_{1-X}Se₂), copper indium gallium selenide sulfide alloys (CuIn_{X}Ga_{1-X}(S_{Y}Se_{1-Y})₂), copper indium aluminum selenide alloy (CuIn_{X}A_{1-X}Se₂), and copper indium aluminum selenide sulfide alloys (CuIn_{X}Al_{1-X} (S_{Y}Se_{1-Y})₂). For window layer applications, the present invention may also incorporate a variety of substrates. Such substrates may include transparent conductive tin oxide with or without high resistivity buffer layers, transparent conductive indium tin oxide with or without high resistivity buffer layers, transparent conductive cadmium stannate with or without high resistivity buffer layer, transparent conductive zinc oxide with or without high resistivity buffer layers.

Having generally described the invention, the same will be more readily understood by reference to the following examples, which are provided by way of illustration and are not intended as limiting.

1. A heterojunction photovoltaic device comprising:
a substrate;
a first semiconductor layer deposited on the substrate; and
a second semiconductor layer deposited on the first semiconductor wherein the first semiconductor layer has from about nine percent (9 at. %) to about twenty-five percent (25 at. %) oxygen concentration.

2. The photovoltaic device in claim 1, wherein the concentration of oxygen atoms in the first semiconductor deposited layer is about nine percent (9 at. %) to about twenty-three percent (23 at. %).

3. The photovoltaic device in claim 1, wherein the concentration of oxygen atoms in the first semiconductor deposited layer is about fourteen percent (14 at. %) to about twenty-three percent (23 at. %).

4. The photovoltaic device in claim 1 wherein the first and second semiconductor layers are cadmium sulfide and cadmium telluride respectively.

5. The photovoltaic device in claim 1, wherein the first semiconductor layer is deposited utilizing a deposition method having a gas mixture, the gas mixture composed of an inert gas and oxygen, wherein the gas mixture is composed of about 1 percent (1%) to about 5 percent (5%) oxygen.

6. The photovoltaic device in claim 1, wherein the gas mixture is composed of about 2 percent (2%) to about 4 percent (4%) oxygen.

7. The photovotaic device in claim 1, wherein the photovoltaic device has an optical bandgap of greater than about 2.60 eV.

8. The photovotaic device in claim 1, wherein the photovoltaic device has an optical bandgap of greater than about 2.80 eV.

9. The photovotaic device in claim 1, wherein the photovoltaic device has an optical bandgap of greater than about 3.10 eV.

10. The photovoltaic device in claim 1, the substrate further comprising:
a cadmium stannate layer deposited on the substrate to act as a transparent conductive oxide layer (TCO) forming a front contact; and
a zinc stannate layer deposited on the transparent conductive oxide (TCO) layer to form a buffer layer.

11. The photovoltaic device in claim 10, wherein the first semiconductor is a window layer deposited on the buffer layer using a radio frequency sputtering deposition technique, the sputtering technique further including a gas mixture of oxygen gas and argon gas, wherein the oxygen is integrated within the deposited window layer.

12. The photovoltaic device in claim 11, wherein the gas mixture is about one percent (1%) to about five percent (5%) oxygen.

13. The photovoltaic device in claim 11, wherein the gas mixture is about two percent (2%) to about four percent (4%) oxygen.

14. The photovoltaic device in claim 11, wherein the radio frequency sputtering is operated at ambient temperature.

15. A thin-film semiconductor heterojunction photovoltaic device comprising:
a substrate comprising:
a cadmium stannate layer deposited on the substrate to act as a transparent conductive oxide layer forming a front contact; and
a zinc stannate layer deposited on the transparent conductive oxide (TCO) layer to form a buffer layer;
means for increasing the oxygen concentration within a window layer deposited on the substrate, wherein a radio frequency sputtering deposition method is utilized, the deposition method further utilizing a gas mixture of oxygen and argon;
a first semiconductor window layer deposited on the buffer layer using the radio frequency sputtering deposition method, wherein the gas mixture integrate oxygen within the window layer, increasing the oxygen concentration in the deposited window layer to increase optical bandgap and photo to dark conductivity ratio; and
a second semiconductor layer deposited on the window layer to form a heterojunction photovoltaic device.

16. The thin-film semiconductor heterojunction photovoltaic device in claim 15, wherein the gas mixture is about one percent (1%) to about five percent (5%) oxygen.

17. The thin-film semiconductor heterojunction photovoltaic device in claim 15, wherein the gas mixture is about two percent (2%) to about four percent (4%) oxygen.

18. The thin-film semiconductor heterojunction photovoltaic device in claim 15, wherein the window layer has about twelve percent (12 at. %) to about twenty-five percent (25 at. %) oxygen concentration.

19. The thin-film semiconductor heterojunction photovoltaic device in claim 15, wherein the window layer has about fourteen percent (14 at. %) to about twenty-three percent (23 at. %) oxygen concentration.

20. A method of fabricating a semiconductor layer within a heterojunction photovoltaic device, comprising:
placing a substrate within a deposition system chamber;
providing a target material operably connected to an energy source within the system chamber, the target material placed at a pre-determined distance adjacent the substrate;
introducing a gas mixture into the system chamber, the gas mixture composed of an inert gas and oxygen; and
applying power to the energy source at room temperature to initiate deposition of the target material on the substrate, wherein oxygen is incorporated into the deposited layer.

21. The method in claim 20 wherein the gas mixture is composed of about 1 percent (1%) to about 5 percent (5%) oxygen.

22. The method in claim 20 wherein the gas mixture is composed of about 2 percent (2%) to about 4 percent (4%) oxygen.

23. The method according to claim 21 further including the step of controlling the gas mixture ratio by a mass flow rate system operably connected to the deposition chamber.

24. The method according to claim 21 further including the step of distributing the gas mixture by a gas distributor operably connected to the chamber.

25. The method in claim 20 wherein the inert gas is a noble gas.

26. The method in claim 25 wherein the inert gas is selected from the group consisting essentially of Argon, Helium, Neon, Krypton, Xenon, Radon, Nitrogen (N₂), and mixtures thereof.

27. The method according to claim 20, wherein the gas mixture is pretreated to reduce the moisture content of the gas mixture.

28. The method in claim 20 wherein the target material is cadmium sulfide (CdS).

29. The method according to claim 20, wherein the target material is an alloy of zinc cadmium sulfide wherein the alloy is represented by the formula ZnₓCd₁₋ₓS.

30. The method according to claim 20 wherein the substrate is a transparent substrate.

31 The method according to claim 20, further including the steps of:
providing a sample holder operably connected to the chamber;
providing a substrate having a transparent conductive oxide (TCO) layer forming a front contact; and
placing the substrate on the sample holder adjacent to the target surface.

32. The method according to claim 20, further including the steps of:
providing a sample holder operably connected to the chamber;
providing a substrate having a transparent conductive oxide (TCO) layer and a zinc stannate layer, the transparent conductive oxide (TCO) layer forming a front contact and the zinc stannate layer forming a buffer layer; and
placing the substrate on the sample holder adjacent to the target surface.

33. The method according to claim 20 further including the steps of:
controlling the percent of oxygen in the gas mixture by a mass flow rate; and
maintaining a oxygen percentage in the gas mixture between about one percent (1%) and about five percent (5%).

34. The method in claim 20, wherein the deposited layer has an oxygen concentration of about fourteen percent (14 at. %) to about twenty-three percent (23 at. %).

35. The method in claim 20, wherein the deposited layer has an oxygen concentration of about twelve percent (12 at. %) to about twenty-three percent (23 at.

36. The method in claim 20, wherein the deposited layer has an oxygen concentration of about nine percent (9 at. %) to about twenty-three percent (23 at.

37. A sputtering deposition method for fabricating a semiconductor heterojunction photovoltaic device, the sputtered deposition method utilizing a deposition system having a chamber, an energy source, and a gas inlet, the gas inlet and energy source operably connected to the chamber, the gas inlet for injecting gas into the chamber, the energy source for transferring material within the chamber; the deposition method comprising:
placing a substrate in the chamber;
operably connecting a target material to the energy source within the chamber;
placing the target material, at a pre-determined distance, adjacent the substrate;
injecting a gas mixture into the chamber consisting essentially of an inert gas and oxygen; and
applying power to the energy source to deposit a layer of target material on the substrate by operating the system at a partial pressure and room temperature with power applied to the energy source to generate a deposition rate, the gas mixture producing a deposited layer of target material on the substrate wherein the deposited layer contains oxygen.

38. The method according to claim 37 further including the step of mixing the gas mixture to about one percent (1%) to about five percent (5%) of oxygen.

39. The method according to claim 37 further including the step of mixing the gas mixture to about two percent (2%) to about 4 percent (4%) of oxygen.

40. The method according to claim 38 further including the step of placing the target about six centimeters (6 cm.) to about nine centimeters (9 cm.) adjacent the substrate.

41. The method according to claim 38 further including the steps of:
covering the substrate with a shutter, the shutter operably connected to the chamber; and
applying power to the target for about five minutes prior to initiating a deposition rate.

42. The method according to claim 38 further including the step of evacuating the system chamber to a base pressure, the base pressure having a pressure less than 1×10⁻⁶ Torr.

43. The method according to claim 38 further including the step of evacuating the system chamber to a base pressure, the base pressure having a pressure between about 1×10⁻⁶ Torr and about 3×10⁻⁶ Torr.

44. The method in claim 38, wherein the concentration of the oxygen atoms in the deposited layer is about twelve percent (12 at. %) to about twenty-three percent (23 at. %).

45. The method in claim 38, wherein the concentration of the oxygen atoms in the deposited layer is about fourteen percent (14 at. %) to about twenty-three percent (23 at. %).

46. The method in claim 38, wherein the concentration of the oxygen atoms in the deposited layer is about nine percent (9 at. %) to about twenty-three percent (23 at. %).

47. The method in claim 38, wherein the deposition system further includes a mass flow controller operably connected to the chamber for controlling the gas mixture injected into the chamber.

48. The method according to claim 38 further including the step of distributing the gas mixture by a gas distributor operably connected to the chamber.

49. The method according to claim 38 further including the step of placing the target about six centimeters (6 cm.) to about nine centimeters (9 cm.) adjacent the substrate.

50. The method according to claim 38, wherein the gas mixture is pretreated to reduce the moisture content of the gas mixture.

51. The method according to claim 38 further including the steps of:
covering the substrate with a shutter, the shutter operably connected to the chamber; and
pre-sputtering the target for about five minutes prior to initiating a deposition rate.
pre-sputtering the target for about five minutes prior to initiating a deposition rate.

52. The method according to claim 38, wherein the target material is cadmium sulfide (CdS).

53. The method according to claim 38, wherein the target material is an alloy of zinc cadmium sulfide wherein the alloy is represented by the formula ZnₓCd₁₋ₓS.

54. The method according to claim 38 further including the step of distributing the gas mixture by a gas distributor operably connected to the chamber.

55. The method according to claim 38, wherein the system is a radio frequency sputtering system, which further includes a magnetron sputtering gun operably connected to the target material, and a sample holder connected to the chamber for affixing the substrate.

56. The method according to claim 55, further including the steps of producing a substrate, comprised of the steps:
depositing a layer of cadmium stannate on a glass substrate by radio frequency sputtering at ambient temperature to act as a transparent conductive oxide (TCO) layer forming a front contact; and
depositing a layer of zinc stannate on the TCO layer by radio frequency sputtering at ambient temperature to form a buffer layer.

57. The method according to claim 55, wherein the chamber pressure is reduced to a base pressure prior to filling with a gas mixture, the base pressure having a pressure less than 1×10⁻⁶ Torr.

58. The method according to claim 55, wherein the inert gas is a noble gas.

59. The method according to claim 55, wherein the inert gas is selected from the group consisting essentially of Argon, Helium, Neon, Krypton, Xenon, Radon, and Nitrogen (N₂) and mixtures thereof.

60. A radio frequency (RF) sputtering method for making a photovoltaic device, the method comprising the steps of:
providing a cadmium sulfide target;
providing a radio frequency sputtering system having a chamber and a planar magnetron sputtering gun, the gun having a cooling system, an RF power supply, and at least one magnet operably connected to the cadmium sulfide target;
placing a substrate in the chamber, the substrate placed at a pre-determined distance adjacent to the cadmium sulfide target;
introducing a pre-determined gas mixture of oxygen and argon into the chamber; and
operating the planar magnetron sputtering gun at room temperature for sputtering cadmium sulfide onto the substrate to form a cadmium sulfide layer; the cadmium sulfide layer containing an oxygen concentration of about fourteen percent (14 at. %) to about twenty-three (23 at. %).

61. The method according to claim 60 wherein the energy source is a radio frequency magnetron sputtering gun operated at a frequency of about 13.56 megahertz.

62. The method in claim 60 wherein the substrate contains a transparent conductive layer of cadmium stannate.

63. The method according to claim 60, wherein the cadmium sulfide target is an alloy of zinc cadmium sulfide wherein the alloy is represented by the formula ZnₓCd₁₋ₓS.

64. The method according to claim 60 further including the steps of depositing the cadmium sulfide film layer on the substrate with a gas mixture of two percent (2%) oxygen, creating a surface roughness of about three angstroms in the deposited layer.

65. The method in claim 60 wherein the gas mixture is about one percent (1%) to about five percent (5%) oxygen.

66. The method in claim 60 wherein the gas mixture is about two percent (2%) to about four percent (4%) oxygen.

67. The method according to claim 62, wherein the cadmium sulfide layer has an optical bandgap of greater than about 2.60 eV.

68. The method according to claim 62, wherein the cadmium sulfide layer has an optical bandgap of greater than about 2.80 eV.

69. The method according to claim 62, wherein the cadmium sulfide layer has an optical bandgap of greater than about 3.10 eV.
